(19) United States
(12) Patent Application Publication
(10) Pub. No.: US 2020/0194294 A1
(43) Pub. Date: Jun. 18, 2020

(54) SPECTROSCOPIC SYSTEM, OPTICAL INSPECTION METHOD, AND SEMICONDUCTOR DEVICE FABRICATION METHOD

(71) Applicant: SAMSUNG ELECTRONICS CO., LTD., Suwon-si (KR)

(72) Inventors: SUNGHO JANG, Hwaseong-si (KR); Minsu Kim, Suwon-si (KR); Younghoon Sohn, Incheon (KR); Kang-Woong Ko, Seoul (KR); Yusin Yang, Seoul (KR)

(73) Assignee: SAMSUNG ELECTRONICS CO., LTD., Suwon-si (KR)

(21) Appl. No.: 16/444,378

(22) Filed: Jun. 18, 2019

(30) Foreign Application Priority Data
Dec. 14, 2018 (KR) 10-2018-0161933

(51) Int. Cl. H01L 21/67; G01J 3/18; G01J 3/02; G01J 3/04; G01N 21/95; H01L 21/66

(52) U.S. Cl. CPC H01L 21/67288; G01J 3/18; G01J 3/021; H01L 22/20; G01J 3/04; G01N 21/9501; G01J 3/0202

(57) ABSTRACT

A semiconductor fabrication method includes performing a first treatment process on a substrate, inspecting the substrate using a spectroscopic system that includes a light entrance part, a light exit part, a diffraction grating, and a controllable mirror device, and performing a second treatment process of the substrate. The step of performing the inspection process includes separating incident light into a plurality of light rays each having different wavelengths, the incident light being provided to the light entrance part and diffracted at the diffraction grating, and moving the controllable mirror device to reflect a first light ray from among the plurality of light rays having a first wavelength to the light exit part.

### CROSS-REFERENCE TO RELATED APPLICATION

This U.S. nonprovisional application is based on and claims priority under 35 U.S.C § 119 to Korean Patent Application No. 10-2018-0161933 filed on Dec. 14, 2018 in the Korean Intellectual Property Office, the entire contents of which are hereby incorporated by reference.

### BACKGROUND

The present disclosure relates to a spectroscopic system, an optical inspection method, and a semiconductor device fabrication method, and more particularly, to a spectroscopic system including a monochromator, an optical inspection method using the same, and a semiconductor device fabrication method using the same.

As semiconductor processes become finer and more complicated, it is essential to inspect defects that may be produced on semiconductor devices. The detection of defects on semiconductor devices may increase reliability and process yield of semiconductor devices. An optical device may be used to inspect and detect defects on semiconductor devices.

### SUMMARY

Some example embodiments of the present disclosure provide a spectroscopic system capable of quickly adjusting a wavelength of exiting light rays and having improved reliability, an optical inspection method using the same, and a semiconductor device fabrication method using the same.

In accordance with an aspect of the disclosure, a semiconductor device fabrication method includes performing a first treatment process on a substrate; inspecting the substrate on which the first treatment process has been performed using a spectroscopic system that includes a light entrance part, a light exit part, a diffraction grating, and a controllable mirror device; and performing a second treatment process on the substrate after the first treatment process has been performed, wherein the inspecting the substrate includes separating incident light into a plurality of light rays each having different wavelengths, the incident light being provided to the light entrance part and diffracted at the diffraction grating; and moving the controllable mirror device to reflect a first light ray from among the plurality of light rays having a first wavelength to the light exit part.

The controllable mirror device may include a plurality of mirrors, and the moving the controllable mirror device may include independently tilting each mirror from among the plurality of mirrors.

The moving the controllable mirror device may include rotating the controllable mirror device about an axis parallel to a plane on which the controllable mirror device is disposed.

The moving the controllable mirror device may include tilting a first group of mirrors from among the plurality of mirrors to reflect the first light ray to the light exit part and tilting a second group of mirrors from among the plurality of mirrors to reflect a second light ray to the light exit part, the second light ray having a second wavelength different from the first wavelength.

The controllable mirror device may be disposed on an XY plane, the light diffracted at the diffraction grating may diffracted in an X direction, and the tilting the second group of mirrors from among the plurality of mirrors may include tilting each of the second group of mirrors about a Y axis on the XY plane and about a Z axis intersecting the XY plane.

The light exit part may include a first light exit part and a second light exit part, and the moving the controllable mirror device may include controlling a first group of mirrors from among the plurality of mirrors to reflect the first light ray to the first light exit part and controlling a second group of mirrors from among the plurality of mirrors to reflect the first light ray to the second light exit part.

The controllable mirror device may be disposed on an XY plane, the light diffracted at the diffraction grating may be separated in an X direction, and each of the second group of mirrors from among the plurality of mirrors may be rotated about an X axis on the XY plane and about a Z axis intersecting the XY plane.

The inspecting the substrate may further include monitoring the first light ray reflected to the second light exit part.

The light exit part may include a first light exit part and a second light exit part, and the moving the controllable mirror device may include tilting a first group of mirrors from among the plurality of mirrors to reflect the first light ray to the first light exit part, tilting a second group of mirrors from among the plurality of mirrors to reflect the first light ray to the second light exit part, and tilting a third group of mirrors from among the plurality of mirrors to reflect a second light ray from among the plurality of light rays to the first light exit part, the second light ray having a second wavelength different from the first wavelength.

The controllable mirror device may disposed on an XY plane, the light diffracted at the diffraction grating is separated in an X direction, and each of the second group of mirrors from among the plurality of mirrors may be rotated about a Y axis on the XY plane and about a Z axis intersecting the XY plane, and each of the third group of mirrors from among the plurality of mirrors may be rotated about an X axis on the XY plane and about the Z axis.

The spectroscopic system may further include a focusing mirror between the controllable mirror device and the light exit part, and the focusing mirror may concentrate light rays reflected from the controllable mirror device.

The performing the first treatment process may include performing a thin-layer deposition process, and the performing the second treatment process may include performing one from among a patterning process, an etching process, and a cleaning process.

In accordance with an aspect of the disclosure, an optical inspection method includes providing a target object with a first light ray having a first wavelength to perform an inspection process on the target object, wherein the providing the first light ray includes providing light including a plurality of wavelengths to a diffraction grating to separate the light into a plurality of light rays each having a different wavelength, the first light ray being included among the plurality of light rays; reflecting the separated plurality of light rays from a controllable mirror device on a downstream side of the diffraction grating in a light traveling direction such that the first light ray is reflected to a light exit part; and providing the target object with the first light ray exiting the light exit part, and wherein the reflecting the separated plurality of light rays includes rotating the controllable mirror device on a plane so as to reflect the first light ray to the light exit part, the controllable mirror device being disposed on the plane.

The plurality of light rays reflected from the controllable mirror device may be reflected to a focusing mirror between the controllable mirror device and the light exit part and may be reflected from the focusing mirror, each of the plurality of light rays having a different focal point, wherein the first light ray from among the plurality of light rays is focused on an opening of the light exit part.

The controllable mirror device may include a plurality of mirrors, and the rotating the controllable mirror device may include independently controlling each mirror from among the plurality of mirrors.

The light exit part may include a first light exit part and a second light exit part, and the optical inspection method may further include monitoring the first light ray reflected to the second light exit part.

The performing the inspection process may include tilting a first group of mirrors from among the plurality of mirrors to provide the first light ray to the first light exit part and tilting a second group of mirrors from among the plurality of mirrors to reflect the first light ray to the second light exit part.

The controllable mirror device may disposed on an XY plane, the light diffracted at the diffraction grating is separated in an X direction, and each of the second group of mirrors from among the plurality of mirrors may be rotated about an X axis on the XY plane and about a Z axis intersecting the XY plane.

The performing the inspection process may include tilting a first group of mirrors from among the plurality of mirrors to reflect the first light ray to the light exit part and tilting a second group of mirrors from among the plurality of mirrors to reflect a second light ray to the light exit part, the second light ray having a second wavelength different from the first wavelength.

The controllable mirror device may be disposed on an XY plane, the light diffracted at the diffraction grating may be separated in an X direction, and each of the second group of mirrors from among the plurality of mirrors may be rotated about a Y axis on the XY plane and about a Z axis intersecting the XY plane.

The light exit part may include a first light exit part and a second light exit part, and the performing the inspection process may include tilting a first group of mirrors from among the plurality of mirrors to reflect the first light ray to the first light exit part, tilting a second group of mirrors from among the plurality of mirrors to reflect the first light ray to the second light exit part, and tilting a third group of mirrors from among the plurality of mirrors to reflect a second light ray from among the plurality of light rays to the first light exit part, the second light ray having a second wavelength different from the first wavelength.

The controllable mirror device may be disposed on an XY plane, the light diffracted at the diffraction grating may be separated in an X direction, and each of the second group of mirrors from among the plurality of mirrors may be rotated about a Y axis on the XY plane and about a Z axis intersecting the XY plane, and each of the third group of mirrors from among the plurality of mirrors may be rotated about an X axis on the XY plane and about the Z axis.

In accordance with an aspect of the disclosure, a spectroscopic system includes a light entrance part to which incident light including a plurality of wavelengths is provided; a diffraction grating that diffracts and separates the incident light into a plurality of light rays each having a different wavelength; a light exit part that transmits a first light ray having a first wavelength from among the plurality of light rays; a controllable mirror device between the diffraction grating and the light exit part, the controllable mirror device reflecting the plurality of light rays separated at the diffraction grating; and a controller that controls the controllable mirror device, wherein the controllable mirror device includes a plurality of mirrors, and the controller controls the plurality of mirrors to move independently of each other.

The controller may control the controllable mirror device to reflect the first light ray from among the plurality of light rays to the light exit part.

The spectroscopic system may further include a focusing mirror between the controllable mirror device and the light exit part, the focusing mirror concentrating the plurality of light rays.

The controller may control the controllable mirror device to tilt relative to a plane on which the controllable mirror device is disposed.

The controller may control the controllable mirror device to rotate relative to a plane on which the controllable mirror device is disposed.

The spectroscopic system may further include a collimating mirror between the light entrance part and the diffraction grating, the collimating mirror collimating the incident light.

In accordance with an aspect of the disclosure, a spectroscopic system includes a diffraction grating configured to diffract incident light rays such that a first light ray having a first wavelength exits the diffraction grating in a first direction and a second light ray having a second wavelength exits the diffraction grating in a second direction, the first wavelength being different from the second wavelength and the first direction being different from the second direction; a plurality of mirrors that are individually rotatable upon which the first light ray and the second light ray are incident; a first exit opening; and a controller configured to rotate at least one from among the plurality of mirrors to reflect the first light ray and the second light ray such that the first light ray passes through the first exit opening and the second light ray does not pass through the first exit opening.

The controller may be further configured to rotate a first group of mirrors from among the plurality of mirrors to reflect the first light ray such that the first light ray passes through the first exit opening and to rotate a second group of mirrors from among the plurality of mirrors to reflect the second light ray such that the second light ray passes through the first exit opening.

The spectroscopic system may further include a second exit opening located at a position different from the first exit opening, and the controller may be further configured to rotate a first group of mirrors from among the plurality of mirrors to reflect the first light ray such that the first light ray passes through the first exit opening and to rotate a second group of mirrors from among the plurality of mirrors to reflect the first light ray such that the first light ray passes through the second exit opening.

The controller may be further configured to rotate a third group of mirrors from among the plurality of mirrors to reflect the second light ray such that the second light ray passes through the first exit opening.

The plurality of mirrors may be arranged in a plane.

The spectroscopic system may further include a focusing mirror configured to adjust a focal point of the first light ray to be located at the first exit opening.

An optical inspection apparatus may include the spectroscopic system in accordance with the above-noted aspect of the disclosure; a light source configured to emit the first light ray and the second light ray to be incident upon the spectroscopic system; and a light sensor, the spectroscopic system may be configured to transmit the first light ray to be incident upon a substrate, and the light sensor may be configured to sense a light ray reflected from the substrate.

Details of other example embodiments are included in the description and drawings.

### BRIEF DESCRIPTION OF THE DRAWINGS

FIG. 1 illustrates an optical inspection apparatus according to an example embodiment.

FIG. 2A illustrates a spectroscopic system shown in FIG. 1.

FIG. 2B illustrates that an incident light is separated by a diffraction grating shown in FIG. 2A.

FIG. 3 illustrates a controllable mirror device, a focusing mirror, and a light exit part shown in FIG. 2A.

FIGS. 4A and 4B illustrate that a specific-wavelength light is selectively received by the controllable mirror device shown in FIG. 3.

FIG. 5 illustrates a flow chart showing a semiconductor device fabrication method using the spectroscopic system shown in FIG. 2A.

FIG. 6A illustrates a flow chart showing a semiconductor device fabrication method according to an example embodiment.

FIG. 6B illustrates an inspection process according to the fabrication method shown in FIG. 6A.

FIG. 7A illustrates a flow chart showing a semiconductor device fabrication method according to an example embodiment.

FIG. 7B illustrates an inspection process according to the fabrication method shown in FIG. 7A.

FIG. 8 illustrates an inspection process according to an example embodiment.

### DETAILED DESCRIPTION OF EMBODIMENTS

Some example embodiments will be described below in detail with reference to the accompanying drawings.

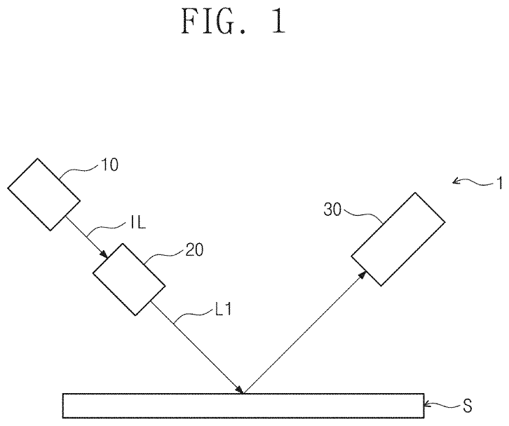

FIG. 1 illustrates an optical inspection apparatus 1 according to some example embodiments of the present disclosure. Referring to FIG. 1, the optical inspection apparatus 1 may be configured to provide a target object with light to perform an optical inspection process. The following will describe an example in which the target object is a substrate S, but the target object may be any other various substances capable of being optically inspected.

The optical inspection apparatus 1 may provide the substrate S with light to perform an optical inspection process on the substrate S. In this description, the substrate S may be a semiconductor substrate for fabricating a semiconductor device or a glass substrate for manufacturing a flat display device, but the present disclosure is not limited thereto.

The optical inspection apparatus 1 may include a light source 10, a spectroscopic system 20, and a light receiver (i.e., light sensor) 30. The optical inspection apparatus 1 may be, for example, a spectroscopic ellipsometer, but alternatively may be any other optical inspection device that includes the spectroscopic system 20.

The light source 10 may emit a light ray IL. The light ray IL may be a broadband light ray. In other words, the light ray IL may include a plurality of wavelengths. For example, the light ray IL may be white light, but the present disclosure is not limited thereto. The light ray IL may be incident upon the spectroscopic system 20.

The spectroscopic system 20 may include a monochromator. The spectroscopic system 20 may be configured to select and/or change a specific wavelength of the light ray IL. For example, the spectroscopic system 20 may select a first light ray L1 having a first wavelength from the light ray IL and emit the first light ray L1. The spectroscopic system 20 may be disposed on a front side (i.e., a downstream side in a light traveling direction) of the light source 10. In this description, it is assumed that front and rear sides respectively face forward and backward to a traveling direction of light. In other words, the front side is a downstream side in a light traveling direction and the rear side is an upstream side in the light traveling direction.

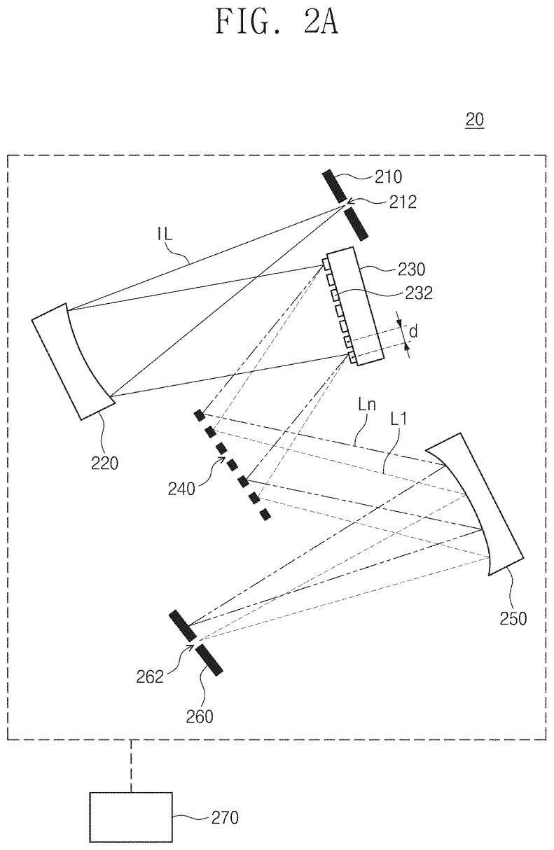

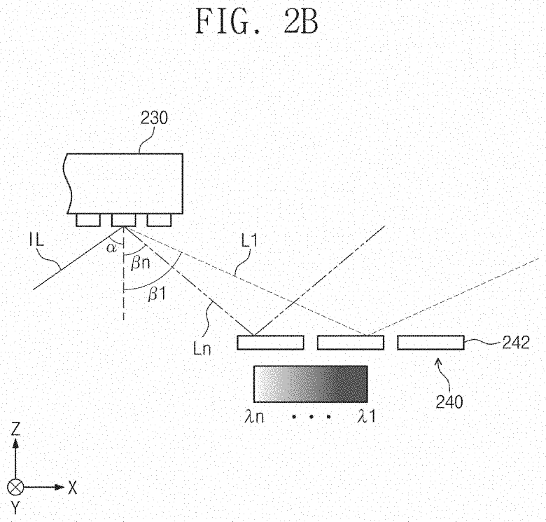

FIG. 2A illustrates the spectroscopic system 20 shown in FIG. 1. Referring to FIG. 2A, the spectroscopic system 20 may include a light entrance part 210, a collimating mirror 220, a diffraction grating 230, a controllable mirror device 240, a focusing mirror 250, and a light exit part 260. In this description, various solid lines are illustrated to individually indicate light rays having different wavelengths so as to facilitate the present disclosure. In addition, light traveling paths (e.g., reflection paths) may be exaggerated, distorted, or different from actual traveling paths.

The light entrance part 210 may include a slit. The light entrance part 210 may have a first opening 212 through which the light ray IL is introduced into the spectroscopic system 20. The light ray IL may be a broadband light (e.g., white light).

The collimating mirror 220 may be disposed between the light entrance part 210 and the diffraction grating 230. The collimating mirror 220 may be placed on a front side of the light entrance part 210. The collimating mirror 220 may collimate the light ray IL. The light ray IL may be reflected from the collimating mirror 220 and then directed toward the diffraction grating 230.

The diffraction grating 230 may be placed on a front side of the collimating mirror 220. The diffraction grating 230 may have grooves and/or ridges 232 that diffract the light ray IL. The grooves 232 may be arranged at a regular pitch d. Here, the pitch d refers to a distance between the same point on adjacent grooves or ridges 232. The diffraction grating 230 may split the light ray IL into several light rays according to wavelength.

FIG. 2B illustrates that the light ray IL is separated by the diffraction grating 230 shown in FIG. 2A. Referring to FIG. 2B, when the light ray IL is incident at an incident angle α, and when the diffraction grating 230 has a pitch d, the light ray IL may be split into diffracted light rays L1 to Ln according to wavelength. Wavelengths of the diffracted light rays may be determined by Equation 1 given below. In Equation 1, m may indicate a diffraction order, and β may denote a diffraction angle.

mλ=d(sin α±sin β) [Equation 1]

The broadband light ray IL diffracted by the diffraction grating 230 may be separated into several light rays each having their own wavelengths. In the drawings, for example, the diffracted light rays are illustrated as a first light ray L1 and an nth light ray Ln that have different wavelengths. The first light ray L1 may have a first wavelength λ1, and the nth light ray Ln may have an nth wavelength λn different from the first wavelength λ1. For example, the first wavelength λ1 may be longer than the nth wavelength kn.

Referring together to FIGS. 2A and 2B, the controllable mirror device 240 may be installed between the diffraction grating 230 and the light exit part 260. The controllable mirror device 240 may be placed on a front side of the diffraction grating 230. As shown in FIG. 2B, the controllable mirror device 240 may be disposed on an XY plane extended in an X direction and a Y direction. In this description, the X direction may be defined to refer to a direction along which the light ray IL is separated and the Y direction may be perpendicular to the X direction.

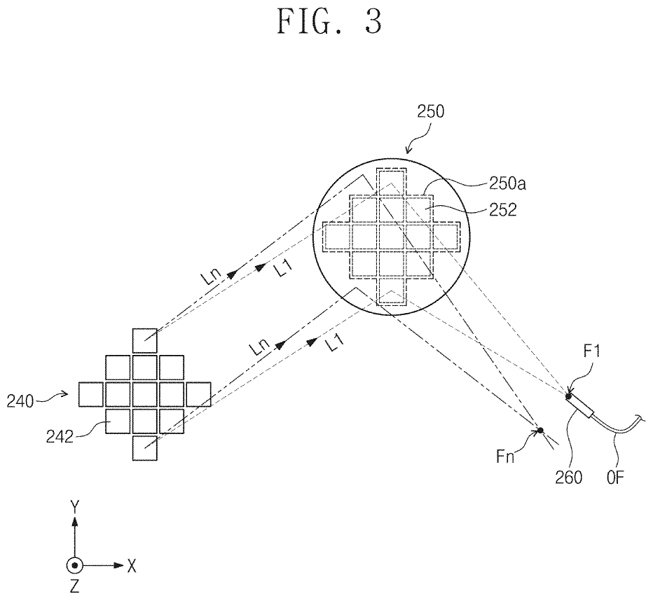

FIG. 3 illustrates the controllable mirror device 240, the focusing mirror 250, and the light exit part 260 shown in FIG. 2A. Referring to FIG. 3, the controllable mirror device 240 may be controlled to selectively provide the light exit part 260 with a specific-wavelength light ray chosen among the diffracted light rays L1 to Ln diffracted by the diffraction grating 230. For example, the controllable mirror device 240 may be controlled such that the light exit part 260 selectively receives the first light ray L1 among the diffracted light rays L1 to Ln.

The controllable mirror device 240 may be a mirror array including a plurality of mirrors 242. For example, the controllable mirror device 240 may be a micro-mirror array. FIG. 3 shows a mirror array in which fifteen mirrors 242 are arranged in a grid shape, but the number and arrangement of mirrors 242 in the mirror array may not be limited thereto. In other embodiments, the controllable mirror device 240 may be an optical device capable of changing a focal point. For example, the controllable mirror device 240 may be an optical device capable of partially changing a focal point.

The focusing mirror 250 may reflect the diffracted light rays L1 to Ln reflected from the controllable mirror device 240. To facilitate understanding, the focusing mirror 250 is illustrated to have a virtual controllable mirror equivalent region 250a corresponding to the controllable mirror device 240 and virtual mirror equivalent sections 252 corresponding to the mirrors 242.

The focusing mirror 250 may be placed between the controllable mirror device 240 and the light exit part 260. The focusing mirror 250 may be disposed on a front side of the controllable mirror device 240. The focusing mirror 250 may concentrate (i.e., focus) each of the diffracted light rays L1 to Ln reflected from the controllable mirror device 240.

The controllable mirror device 240 may control the first light ray L1 to travel toward a second opening (i.e., exit opening, see 262 of FIG. 2A) of the light exit part 260. For example, the controllable mirror device 240 may control the first light ray L1 to be focused at the second opening 262 of the light exit part 260 (see F1 of FIG. 3). The light exit part 260 may deliver the first light ray L1 through an optical fiber OF. In contrast, the nth light ray Ln may concentrate on a location away from the light exit part 260 (see Fn of FIG. 3). Therefore, the nth light ray Ln may be neither delivered toward the second opening 262 nor output in any other manner.

Referring back to FIG. 2A, the light exit part 260 may include a slit. Only the first light ray L1, for example, may flow out of the spectroscopic system 20 through the second opening 262 of the light exit part 260. The light exit part 260 may be connected to the optical fiber (see OF of FIG. 3) or the like.

A controller 270 may control the light entrance part 210, the collimating mirror 220, the diffraction grating 230, the controllable mirror device 240, the focusing mirror 250, and the light exit part 260. The controller 270 may control the controllable mirror device 240 to select a specific-wavelength light ray. For example, the controller 270 may control the controllable mirror device 240 to move. In certain embodiments, the controller 270 may control the controllable mirror device 240 to rotate or tilt relative to the XY plane. The controller 270 may include hardware or software or a combination of hardware and software. For example, the controller 270 may include a processor.

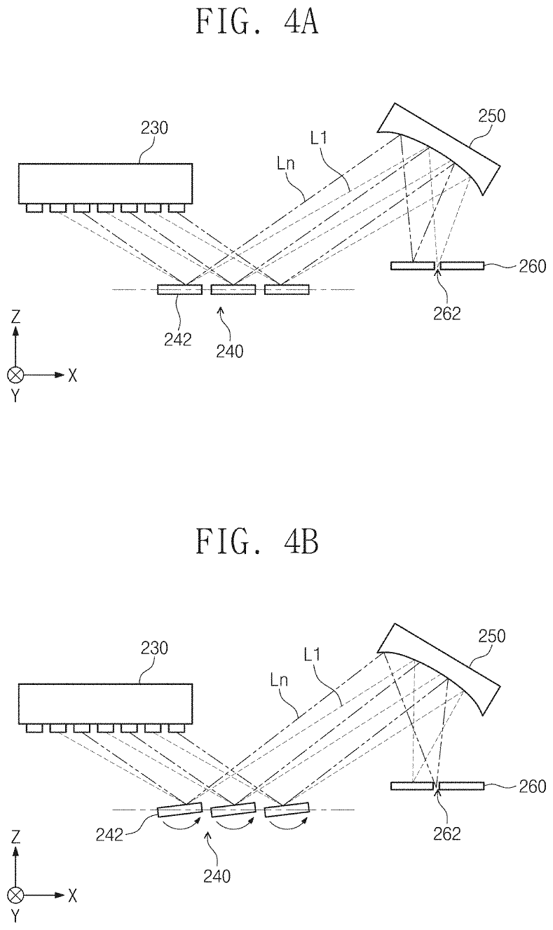

FIGS. 4A and 4B illustrate an example embodiment in which a specific-wavelength light ray is selectively reflected by the controllable mirror device 240 shown in FIG. 3. The following will describe an example in which the controllable mirror device 240 selects a specific light ray with reference to FIGS. 4A and 4B.

Referring to FIGS. 4A and 4B, a light may be selectively sent based on the tilting or rotation of the controllable mirror device 240. According to a tilted angle of the controllable mirror device 240, diffracted lights may be selected differently. For example, the first light L1 may be sent to the light exit part 260 as shown in FIG. 4A, but when the controllable mirror device 240 is tilted as shown in FIG. 4B, the nth light Ln may be sent to the light exit part 260.

Based on the tilted angle, the controllable mirror device 240 may select a desired light ray intended to exit the spectroscopic system 20. In addition, the controller 270 may move or rotate at least one mirror 242 of the controllable mirror device 240. As shown in FIG. 4B, the plurality of mirrors 242 may be tilted with respect to an X axis and rotated about a Y axis respectively.

Referring back to FIG. 1, the first light ray L1 emitted from the spectroscopic system 20 may be reflected from the substrate S, and then incident onto the light receiver 30. The light receiver 30 may receive and analyze the first light ray L1 reflected from the substrate S. The light receiver 30 may include, for example but not limited to, a charge coupled diode (CCD). Although not shown, the light receiver 30 may include a display where signals are processed, analyzed, and visually expressed.

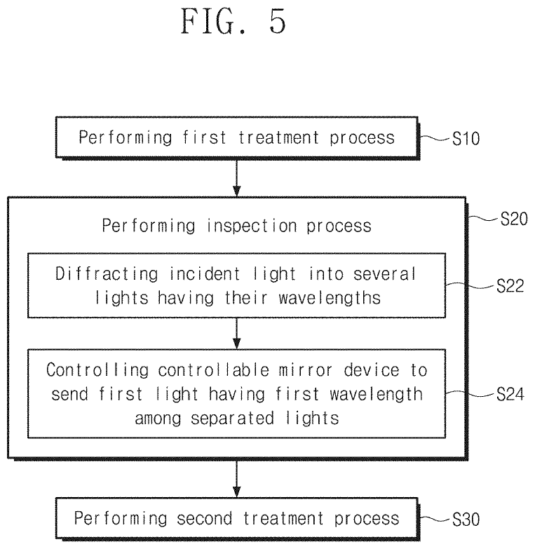

FIG. 5 illustrates a flow chart showing a semiconductor device fabrication method using the spectroscopic system 20 shown in FIG. 2A. Referring to FIGS. 2A to 5, it will be described how a semiconductor device is fabricated according to example embodiments of the present disclosure.

A first treatment process may be performed on the substrate S (S10). The first treatment process may be, for example but not limited to, a thin-layer deposition process.

An inspection process may be performed on the substrate S on which the first treatment process has been completed (S20). The optical inspection apparatus 1 may be used to perform the inspection process.

The light source 10 may emit the light ray IL. The light ray IL may be a broadband light. For example, the light ray IL may be white light, but the present disclosure is not limited thereto.

The spectroscopic system 20 may include a monochromator. The spectroscopic system 20 may be configured to select and/or change a specific wavelength of the light ray IL. For example, the spectroscopic system 20 may select the first light ray L1 having a first wavelength from the light ray IL, thereby emitting only the first light ray L1.

The light ray IL may be introduced into the spectroscopic system 20 through the first opening 212 of the light entrance part 210, and the collimating mirror 220 may collimate the light ray IL. The light ray IL may be reflected from the collimating mirror 220, and then the diffraction grating 230 may separate the light ray IL into several light rays each having their own wavelengths (S22). The controllable mirror device 240 may receive the diffracted light rays L1 to Ln that have been separated from each other and each having their own wavelengths. The controllable mirror device 240 may selectively provide the light exit part 260 with a specific-wavelength light ray among the diffracted light rays L1 to Ln (S24). The controllable mirror device 240 may be controlled such that the first light ray L1 among the diffracted light rays L1 to Ln is selected to travel toward the second opening 262 of the light exit part 260. The controllable mirror device 240 may be controlled such that only the first light ray L1 is focused on the second opening 262 of the light exit part 260. The focusing mirror 250 may concentrate each of the diffracted light rays L1 to Ln reflected from the controllable mirror device 240. The first light ray L1 may exit the spectroscopic system 20 through the second opening 262 of the light exit part 260. The inspection process may inspect results of the substrate S on which the first treatment process has been completed. For example, the inspection process may be a process that measures thicknesses or the like of thin-layers and/or patterns deposited on the substrate S.

The substrate S may undergo a second treatment process that is subsequently performed after the first treatment process (S30). The second process may be, for example but not limited to, a various subsequent process such as a patterning process, an etching process, a cleaning process, or an oxidation process. The second treatment process may be performed on a substrate that passes the inspection process (e.g., on a substrate acquiring appropriate results of the inspection process), but when the inspection process determines that results of the first treatment process are inappropriate, the first treatment process may be repeatedly performed.

According to the present disclosure, the controllable mirror device 240 may be controlled to move to select a specific-wavelength light ray. For example, at least a portion of the controllable mirror device 240 may be rotated or tilted relative to a plane on which the controllable mirror device 240 is disposed, and thus a specific-wavelength light ray may be selected. The controllable mirror device 240 may have relatively smaller volume and weight than those of other optical components (e.g., the diffraction grating 230), and accordingly may be easily moved. For example, it may take several milliseconds to move the mirrors 242 of the controllable mirror device 240, but it may take several seconds to move other optical components (e.g., the diffraction grating 230). As a result, it may be easy to precisely control the spectroscopic system 20 at extremely small angles. Furthermore, the spectroscopic system 20 may quickly adjust the wavelength of light rays exiting the optical inspection apparatus 1.

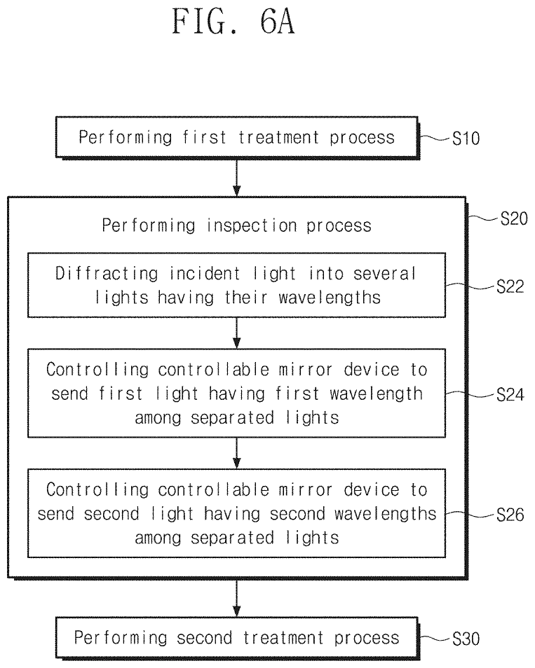

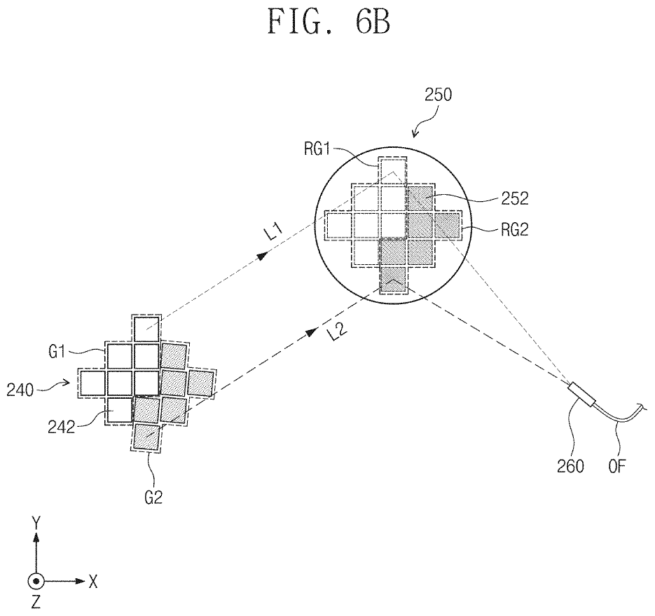

FIG. 6A illustrates a flow chart showing a semiconductor device fabrication method according to example embodiments of the present disclosure. FIG. 6B illustrates an inspection process according to the fabrication method shown in FIG. 6A. In the embodiment that follows, a description of features repetitive to those of the semiconductor device fabrication method discussed above with reference to FIG. 5 will be omitted in the interest of brevity.

Referring to FIGS. 6A and 6B, the steps S10, S22, and S24 may be identical or similar to those of the semiconductor device fabrication method discussed above with reference to FIG. 5. In the present embodiment, the semiconductor device fabrication method may further include that the controllable mirror device 240 is controlled to reflect a second light ray L2 having a second wavelength among the diffracted lights rays L1 to Ln (S26).

Referring to FIG. 6B, the controller 270 may move at least one mirror 242 of the controllable mirror device 240. For example, the controller 270 may independently control a first group G1 and a second group G2 each of which consists of at least one mirror 242 of the controllable mirror device 240. The controller 270 may hold the mirrors 242 of the first group G1 in place and move the mirrors 242 of the second group G2. The controller 270 may hold the mirrors 242 of the first group G1 in place and rotate the mirrors 242 of the second group G2. For example, the controller 270 may rotate the mirrors 242 of the second group G2 about the Y axis (or a Y-directional axis) relative to the XY plane. The mirrors 242 of the second group G2 may also be rotated about the Z axis respectively.

Therefore, the mirrors 242 of the first group G1 may reflect the first light ray L1 to the light exit part 260, and the mirrors 242 of the second group G2 may reflect the second light ray L2 to the light exit part 260. The focusing mirror 250 may have mirror equivalent sections 252 of a first equivalent region RG1 that corresponds to the first group G1, which mirror equivalent sections 252 may concentrate the first light ray L1 on the light exit part 260, and also have other mirror equivalent sections 252 of a second equivalent region RG2 that corresponds to the second group G2, which other mirror equivalent sections 252 may concentrate the second light ray L2 on the light exit part 260. As a result, the light exit part 260 may transmit both the first light ray L1 and the second light ray L2 to the optical fiber OF.

Because the spectroscopic system 20 is configured to selectively transmit the light rays L1 and L2 having different wavelengths, the spectroscopic system 20 may provide improved responsiveness and/or stability.

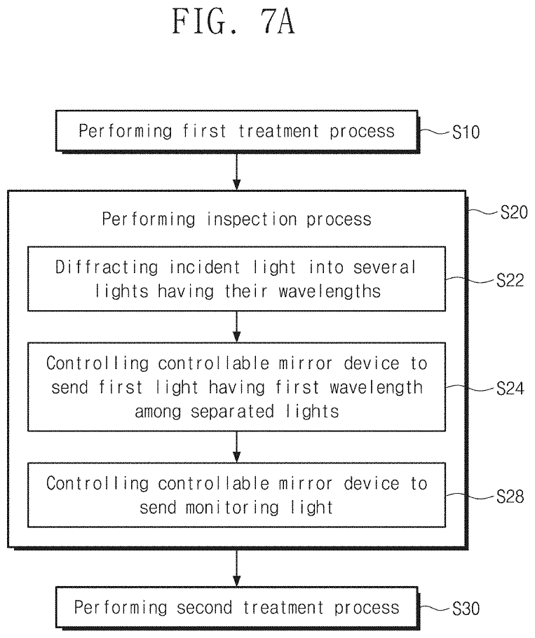

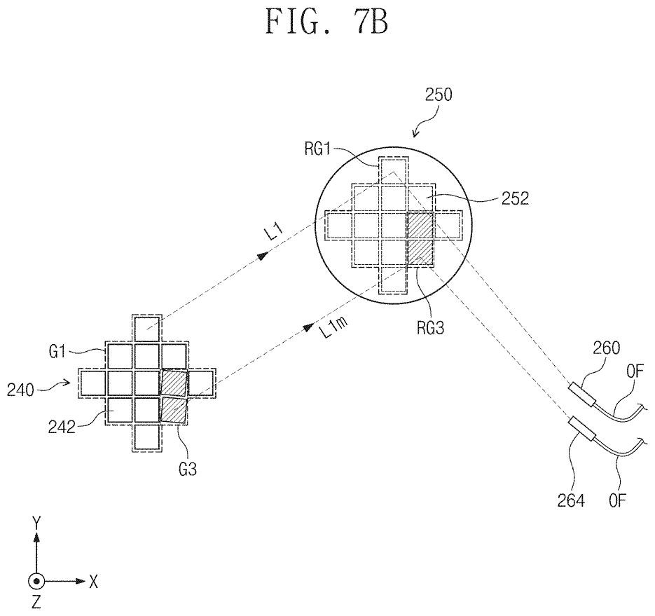

FIG. 7A illustrates a flow chart showing a semiconductor device fabrication method according to example embodiments of the present disclosure. FIG. 7B illustrates an inspection process according to the fabrication method shown in FIG. 7A. In the embodiment that follows, a description of features repetitive to those of the semiconductor device fabrication method discussed above with reference to FIG. 5 will be omitted in the interest of brevity.

Referring to FIGS. 7A and 7B, the steps S10, S22, and S24 may be identical or similar to those of the semiconductor device fabrication method discussed above with reference to FIG. 5. According to the present embodiment, the semiconductor device fabrication method may further include that the controllable mirror device 240 is controlled to send a monitoring light ray (S28).

Referring to FIG. 7B, the controller 270 may move at least one mirror 242 of the controllable mirror device 240. For example, the controller 270 may independently control a first group G1 and a third group G3 each of which consists of at least one mirror 242 of the controllable mirror device 240. The controller 270 may hold the mirrors 242 of the first group G1 in place and move the mirrors 242 of the third group G3. The controller 270 may hold the mirrors 242 of the first group G1 in place and rotate the mirrors 242 of the third group G3. For example, the controller 270 may control the mirrors 242 of the third group G3 to rotate about the X axis (or an X-directional axis) relative to the XY plane. The mirrors 242 of the third group G3 may also be rotated about Z axis respectively.

In addition, the spectroscopic system 20 may further include an additional light exit part 264. The mirrors 242 of the first group G1 may reflect the first light ray L1 to the light exit part 260, and the mirrors 242 of the third group G3 may reflect a monitoring light ray L1m to the additional light exit part 264. The monitoring light ray L1m reflected to the additional light exit part 264 may have a first wavelength, and may be substantially the same as the first light ray L1.

The focusing mirror 250 may have mirror equivalent sections 252 of a first equivalent region RG1 that corresponds to the first group G1, which mirror equivalent sections 252 may concentrate the first light ray L1 on the light exit part 260, and also have other mirror equivalent sections 252 of a third equivalent region RG3 that corresponds to the third group G3, which other mirror equivalent sections 252 may concentrate the monitoring light ray L1m on the additional light exit part 264. Therefore, as shown in FIG. 7B, the light exit part 260 may transmit the first light ray L1 to the optical fiber OF, and the additional light exit part 264 may transmit the monitoring light ray L1m to an additional optical fiber OF.

The monitoring light ray L1m may be transmitted to the additional light exit part 264, and thus used to monitor the inspection process. For example, the monitoring light ray L1m may be used to monitor an output and/or a wavelength of the first light ray L1.

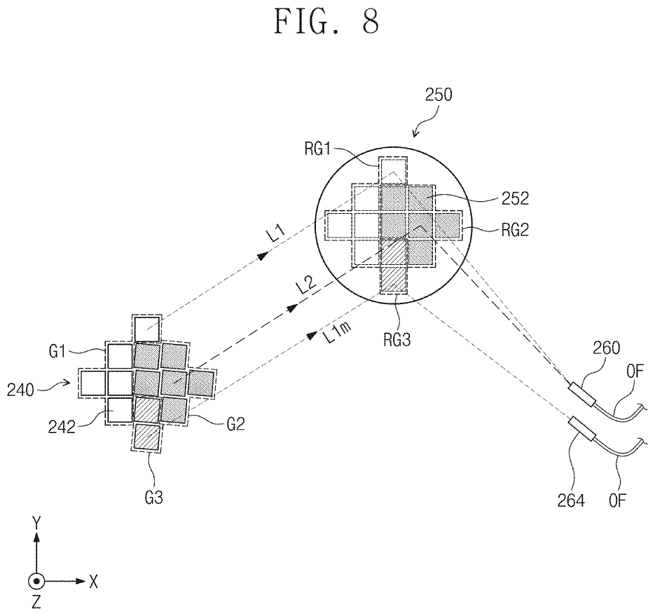

FIG. 8 illustrates an inspection process according to example embodiments of the present disclosure. In the embodiment that follows, a description of features repetitive to those of the semiconductor device fabrication method discussed above with reference to FIGS. 5 to 7B will be omitted in the interest of brevity.

Referring to FIG. 8, the controller 270 may move at least one mirror 242 of the controllable mirror device 240. For example, the controller 270 may independently control a first group G1, a second group G2, and a third group G3 each of which consists of at least one mirror 242 of the controllable mirror device 240. The controller 270 may hold the mirrors 242 of the first group G1 in place and move the mirrors 242 of the second and third groups G2 and G3. The controller 270 may hold the mirrors 242 of the first group G1 in place and rotate the mirrors 242 of the second and third groups G2 and G3 differently. For example, the controller 270 may control the mirrors 242 of the second group G2 to rotate about the Y axis relative to the XY plane, and also control the mirrors 242 of the third group G3 to rotate about the X axis relative to the XY plane. The mirrors 242 of the second group G2 may also be rotated about the Z axis respectively. The mirrors 242 of the third group G3 may also be rotated about Z axis respectively. Rotated angles of the mirrors 242 of the second group G2 and the third group G3 may be different.

The mirrors 242 of the first group G1 may reflect the first light ray L1 to the light exit part 260, the mirrors 242 of the second group G2 may reflect the second light ray L2 to the light exit part 260, and the mirrors 242 of the third group G3 may reflect the monitoring light ray L1m to the additional light exit part 264. The monitoring light ray L1m sent to the additional light exit part 264 may have a first wavelength, and may be substantially the same as the first light ray L1.

The focusing mirror 250 may have first mirror equivalent sections 252 of a first equivalent region RG1 that corresponds to the first group G1, which first mirror equivalent sections 252 may concentrate the first light ray L1 on the light exit part 260, also have second mirror equivalent sections 252 of a second equivalent region RG2 that corresponds to the second group G2, which second mirror equivalent sections 252 may concentrate the second light ray L2 on the light exit part 260, and further have third mirror equivalent sections 252 of a third equivalent region RG3 that corresponds to the third group G3, which third mirror equivalent sections 252 may concentrate the monitoring light ray L1m on the additional light exit part 264. Therefore, the light exit part 260 may transmit the first light ray L1 and the second light ray L2 to the optical fiber OF, and the additional light exit part 264 may transfer the monitoring light ray L1m to the additional optical fiber OF.

The monitoring light ray L1m may be sent to the additional light exit part 264, and thus used to monitor the inspection process. For example, the monitoring light ray L1m may be used to monitor an output and/or a wavelength of the first light ray L1.

According to example embodiments of the present disclosure, a controllable mirror device may be controlled to move to select a specific-wavelength light ray. For example, at least a portion of the controllable mirror device may be rotated or tilted relative to a plane on which the controllable mirror device is disposed, and thus a specific-wavelength light ray may be selected. The controllable mirror device may have relatively smaller volume and weight than those of other optical components (e.g., a diffraction grating), and accordingly may be easily moved. As a result, it may be easy to precisely control an optical inspection apparatus at extremely small angles and to promptly perform an inspection process.

The effects of the present disclosure are not limited to the aforementioned effects. Other effects, which are not mentioned above, will be apparently understood by one skilled in the art from the foregoing description and accompanying drawings.

These embodiments herein are presented to facilitate understanding of the present disclosure and should not limit the scope of the present disclosure, and it is intended that the present disclosure cover various combinations, modifications, and variations. The technical protection scope of the present disclosure will be defined by the technical spirit of the appended claims, and is intended to include all modifications and equivalents substantially falling within the spirit and scope of the disclosure while not being limited by the descriptions in the appended claims.

1. A semiconductor device fabrication method, comprising:
performing a first treatment process on a substrate;
inspecting the substrate on which the first treatment process has been performed using a spectroscopic system that includes a light entrance part, a light exit part, a diffraction grating, and a controllable mirror device; and
performing a second treatment process on the substrate after the first treatment process has been performed,
wherein the inspecting the substrate comprises:
separating incident light into a plurality of light rays each having different wavelengths, the incident light being provided to the light entrance part and diffracted at the diffraction grating; and
moving the controllable mirror device to reflect a first light ray from among the plurality of light rays having a first wavelength to the light exit part.

2. The semiconductor device fabrication method of claim 1, wherein the controllable mirror device includes a plurality of mirrors, and
wherein the moving the controllable mirror device comprises independently tilting each mirror from among the plurality of mirrors.

3. The semiconductor device fabrication method of claim 1, wherein the moving the controllable mirror device comprises rotating the controllable mirror device about an axis parallel to a plane on which the controllable mirror device is disposed.

4. The semiconductor device fabrication method of claim 2, wherein the moving the controllable mirror device comprises tilting a first group of mirrors from among the plurality of mirrors to reflect the first light ray to the light exit part and tilting a second group of mirrors from among the plurality of mirrors to reflect a second light ray to the light exit part, the second light ray having a second wavelength different from the first wavelength.

5. The semiconductor device fabrication method of claim 4, wherein the controllable mirror device is disposed on an XY plane, and the light diffracted at the diffraction grating is diffracted in an X direction,
wherein the tilting the second group of mirrors from among the plurality of mirrors comprises tilting each of the second group of mirrors about a Y axis on the XY plane and about a Z axis intersecting the XY plane.

6. The semiconductor device fabrication method of claim 2, wherein the light exit part includes a first light exit part and a second light exit part,
wherein the moving the controllable mirror device comprises controlling a first group of mirrors from among the plurality of mirrors to reflect the first light ray to the first light exit part and controlling a second group of mirrors from among the plurality of mirrors to reflect the first light ray to the second light exit part.

7. The semiconductor device fabrication method of claim 6, wherein the controllable mirror device is disposed on an XY plane, and the light diffracted at the diffraction grating is separated in an X direction,
wherein each of the second group of mirrors from among the plurality of mirrors is rotated about an X axis on the XY plane and about a Z axis intersecting the XY plane.

8. The semiconductor device fabrication method of claim 6, wherein the inspecting the substrate further comprises monitoring the first light ray reflected to the second light exit part.

9. The semiconductor device fabrication method of claim 2, wherein the light exit part includes a first light exit part and a second light exit part, and
wherein the moving the controllable mirror device comprises tilting a first group of mirrors from among the plurality of mirrors to reflect the first light ray to the first light exit part, tilting a second group of mirrors from among the plurality of mirrors to reflect the first light ray to the second light exit part, and tilting a third group of mirrors from among the plurality of mirrors to reflect a second light ray from among the plurality of light rays to the first light exit part, the second light ray having a second wavelength different from the first wavelength.

10. The semiconductor device fabrication method of claim 9, wherein the controllable mirror device is disposed on an XY plane, and the light diffracted at the diffraction grating is separated in an X direction,
wherein each of the second group of mirrors from among the plurality of mirrors is rotated about a Y axis on the XY plane and about a Z axis intersecting the XY plane, and each of the third group of mirrors from among the plurality of mirrors is rotated about an X axis on the XY plane and about the Z axis.

11. The semiconductor device fabrication method of claim 1, wherein the spectroscopic system further includes a focusing mirror between the controllable mirror device and the light exit part, and
wherein the focusing mirror concentrates light rays reflected from the controllable mirror device.

12. The semiconductor device fabrication method of claim 1, wherein
the performing the first treatment process comprises performing a thin-layer deposition process, and
the performing the second treatment process comprises performing one from among a patterning process, an etching process, and a cleaning process.

13. An optical inspection method, comprising
providing a target object with a first light ray having a first wavelength to perform an inspection process on the target object,
wherein the providing the first light ray comprises:
providing light including a plurality of wavelengths to a diffraction grating to separate the light into a plurality of light rays each having a different wavelength, the first light ray being included among the plurality of light rays;
reflecting the separated plurality of light rays from a controllable mirror device on a downstream side of the diffraction grating in a light traveling direction such that the first light ray is reflected to a light exit part; and
providing the target object with the first light ray exiting the light exit part, and
wherein the reflecting the separated plurality of light rays comprises rotating the controllable mirror device on a plane so as to reflect the first light ray to the light exit part, the controllable mirror device being disposed on the plane.

14. The optical inspection method of claim 13, wherein the plurality of light rays reflected from the controllable mirror device are reflected to a focusing mirror between the controllable mirror device and the light exit part and are reflected from the focusing mirror, each of the plurality of light rays having a different focal point, wherein the first light ray from among the plurality of light rays is focused on an opening of the light exit part.

15. The optical inspection method of claim 13, wherein the controllable mirror device includes a plurality of mirrors, and
wherein the rotating the controllable mirror device comprises independently controlling each mirror from among the plurality of mirrors.

16. The optical inspection method of claim 15,
wherein the light exit part includes a first light exit part and a second light exit part, and
wherein the optical inspection method further comprises monitoring the first light ray reflected to the second light exit part.

17. The optical inspection method of claim 16, wherein the performing the inspection process comprises tilting a first group of mirrors from among the plurality of mirrors to provide the first light ray to the first light exit part and tilting a second group of mirrors from among the plurality of mirrors to reflect the first light ray to the second light exit part.

18. The optical inspection method of claim 17, wherein the controllable mirror device is disposed on an XY plane, and the light diffracted at the diffraction grating is separated in an X direction,
wherein each of the second group of mirrors from among the plurality of mirrors is rotated about an X axis on the XY plane and about a Z axis intersecting the XY plane.

19. The optical inspection method of claim 15, wherein the performing the inspection process comprises tilting a first group of mirrors from among the plurality of mirrors to reflect the first light ray to the light exit part and tilting a second group of mirrors from among the plurality of mirrors to reflect a second light ray to the light exit part, the second light ray having a second wavelength different from the first wavelength.

20. The optical inspection method of claim 19, wherein the controllable mirror device is disposed on an XY plane, and the light diffracted at the diffraction grating is separated in an X direction,
wherein each of the second group of mirrors from among the plurality of mirrors is rotated about a Y axis on the XY plane and about a Z axis intersecting the XY plane.

21. The optical inspection method of claim 15, wherein the light exit part includes a first light exit part and a second light exit part,
wherein the performing the inspection process comprises tilting a first group of mirrors from among the plurality of mirrors to reflect the first light ray to the first light exit part, tilting a second group of mirrors from among the plurality of mirrors to reflect the first light ray to the second light exit part, and tilting a third group of mirrors from among the plurality of mirrors to reflect a second light ray from among the plurality of light rays to the first light exit part, the second light ray having a second wavelength different from the first wavelength.

22. The optical inspection method of claim 21, wherein the controllable mirror device is disposed on an XY plane, and the light diffracted at the diffraction grating is separated in an X direction,
wherein each of the second group of mirrors from among the plurality of mirrors is rotated about a Y axis on the XY plane and about a Z axis intersecting the XY plane, and each of the third group of mirrors from among the plurality of mirrors is rotated about an X axis on the XY plane and about the Z axis.

23-35. (canceled)
